(19) United States
(12) Patent Application Publication
(10) Pub. No.: US 2012/0146069 A1
(43) Pub. Date: Jun. 14, 2012

(54) Oxide Based LED BEOL Integration

(75) Inventor: James S. Nakos, Essex Junction, VT (US)

(73) Assignee: International Business Machines Corporation, Armonk, NY (US)

(21) Appl. No.: 12/967,328

(22) Filed: Dec. 14, 2010

(51) Int. Cl. H01L 33/60; H01L 33/36

(52) U.S. Cl. 257/98; 257/99; 438/29; 257/E33.072; 257/E33.062

(57) ABSTRACT

A light emitting diode (LED) structure and method for making a light emitting diode are disclosed. The structure comprises deep trench metal electrodes between which electroluminescent material is disposed on the sidewalls of the electrodes, forming a series of luminescent diode elements stacked horizontally on a substrate.

The method for fabricating the light emitting diode structure can be used for a wide variety of electroluminescent materials.

### BACKGROUND OF THE INVENTION

1. Field of the Invention

This invention pertains to the field of solid state light emitting devices, light emitting diodes or lighting apparatus.

2. Description of Related Art

Typical solid-state light emitting semiconductor diodes (LED's) consist of light emitting material (LEM) deposited as thin films or a combination of thin planar films on the top surface of a substrate and contacted by planar electrodes situated below and above the light emitting material and parallel to the surface of the substrate. Prior art of this type is illustrated in FIG. 1. The light emitting material 110 has various forms and emits light at wavelengths characteristic of the material used. Deposited as a thin planar film, the light emitting material is situated between the top 120 and bottom 130 planar metal electrodes deposited on the top surface of the substrate 140 and the top surface of the light emitting material 110 respectively. Electroluminescence is activated in this device by an applying an electric field to the luminescent material between the electrodes. If the electrodes are not transparent in the wavelength range of interest, they will block much of the light generated in the active region, preventing it from being reaching the outside. One approach to overcome this problem is to use a transparent conductor such as Indium Tin Oxide (ITO) or Zinc oxide over the electroluminescent material as the upper metal electrode stack.

### SUMMARY OF THE INVENTION

The present invention provides a structure for a solid state LED which improves light output and uniformity for LED's with a wide variety of electroluminescent materials deposited on a variety of substrates The invention also increases the active area of the LED's which is involved in the production of light by minimizing the blockage of emitted light by the electrodes. While the invention is compatible with modern semiconductor technology and materials, semiconductor substrates are not a requirement for implementing the device. The invention is applicable to a wide variety of electroluminescent materials such as crystalline or non-crystalline semiconductors or large band-gap insulators which emit visible light. Transparent substrates such as glass or quartz can also be used in the possible embodiments of this invention as discussed later on.

One aspect of this invention is the use of a trench-based electrode structure to increase the volume of electroluminescent material active per unit area on the substrate and maximize the light emitted by electroluminescent material. The electrodes are arranged in closely spaced rows of trenches on the surface of the substrate and apply an electric field across the electroluminescent material located between the sidewalls of neighboring electrodes. The electrodes extend below the light emitting surface of the LED and are perpendicular to this surface. This arrangement leaves the light emitting top surface of the electroluminescent material free from light blocking metal coverage, and permits the fabrication of diodes with greater luminance per unit area currently possible.

In another aspect of the invention various methods of manufacture for several embodiments of this invention are disclosed. The electrode structure is compatible with a wide variety of electroluminescent materials, substrates and LED types and allows light emission from both the front and back surfaces of the LED. These embodiments can be fabricated with state-of-the-art semiconductor processes and materials but are not limited to them.

### BRIEF DESCRIPTION OF THE DRAWINGS

The present invention will be understood by the following detailed description in conjunction with the accompanying drawings. In these drawings like reference numerals designate like structural elements.

FIG. 1 shows a cross-sectional view of a conventional light emitting diode in the prior art.

FIG. 2 shows a perspective view of the light emitting diode according to one embodiment of the current invention.

FIG. 3a shows a cross-sectional view of a light emitting diode according to a first embodiment of the present invention with an opaque insulating substrate which emits light from the top surface of the LED.

FIG. 3b shows a cross-sectional view of a light emitting diode according to a second embodiment of the present invention with a transparent insulating substrate with a reflecting layer which directs light to the top surface for emission

FIG. 3c shows a cross-sectional view of a light emitting diode according to a third embodiment of the present invention with a transparent insulating substrate allowing light emission from both the top and bottom surfaces of the LED.

FIG. 3d shows a cross-sectional view of a light emitting diode according to a fourth embodiment of the present invention wherein a metallic reflecting layer is used as the starting substrate and covered by an insulating layer So that light is emitted from the top LED surface.

FIG. 4a shows a top down view of the light emitting diode according to one embodiment of the current invention.

FIG. 4b shows a cross-sectional view through the section A-A′ shown in FIG. 3a.

FIG. 4c shows a cross-sectional view through the section B-B′ shown in FIG. 3a.

FIG. 5a shows a top down view of the light emitting diode according to another embodiment of the current invention.

FIG. 5b shows a cross-sectional view through the section A-A′ shown in FIG. 4a.

FIG. 5c shows a cross-sectional view through the section B-B′ shown in FIG. 4a.

FIG. 6a illustrates a cross-section of a starting substrate which is conducting and absorptive according to the third embodiment of the present invention.

FIG. 6b illustrates the deposition of appropriate metallic and insulating layers deposited on the conducting absorptive starting substrate.

FIG. 6c illustrates the deposition of the light emitting material on the substrate and deposited layers.

FIG. 6d illustrates the formation of trenches in the light emitting material using standard microelectronic processing techniques.

FIG. 6e illustrates implantation of any dopant ions needed to activate or tune the wavelength of light emitted by the light emitting material.

FIG. 6f illustrates the deposition of a metallic conductor into the trenches formed in the light emitting material

FIG. 6g illustrates the removal of excess metal from the surface of the light emitting material by standard planarizing techniques used in microelectronic technology to form isolated electrodes.

FIG. 7a shows a cross-section through a starting substrate which is insulating and transparent (e.g. glass) according to the third embodiment of the present invention.

FIG. 7b shows a cross-section through a starting substrate which is conducting and reflective (e.g. metal) according to the fourth embodiment of the present invention.

### DETAILED DESCRIPTION OF THE PREFERRED EMBODIMENTS

A light emitting diode structure and method of manufacture thereof is disclosed.

In the following description, numerous specific details are given to provide a thorough understanding of the current invention. It will be understood to persons skilled in the art that the present invention may be practiced without some or all of these specific details.

In addition some well-known process operations are not described in detail in order to succinctly describe the invention and its preferred embodiments.

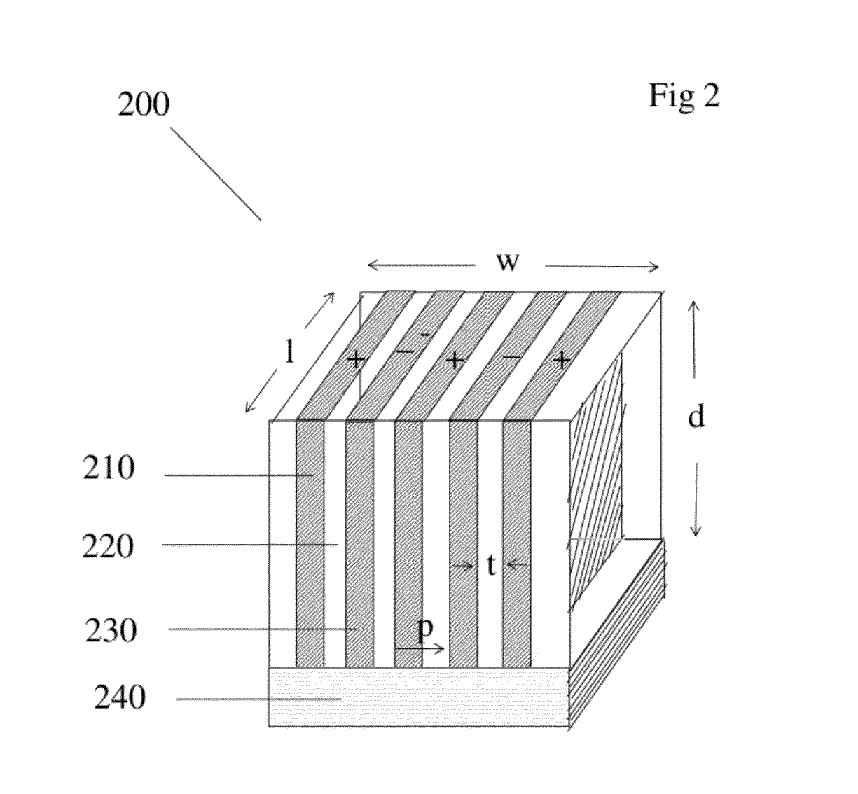

The structure of the invention is illustrated in FIG. 2. The light emitting diode 200 is composed of conducting metal electrodes 210 and 230 and electroluminescent material 220 disposed between them on the substrate 240. An electric field is applied across positive 210 and negative 230 electrodes to activate the electroluminescent material. The electrodes are formed by etching high aspect ratio trenches in the electroluminescent material and subsequently filling these trenches with an electrical conductor. In the embodiment chosen here for illustrative purposes, the electrodes take the shape of inter-digitated combs with positive voltage on one comb and a negative voltage on the other. It is understood by those skilled in the art that other electrode arrangements are possible and not precluded by the example chosen to illustrate the concepts. Under the proper circumstances this arrangement increases the amount of active luminescent material available per unit area of the substrate.

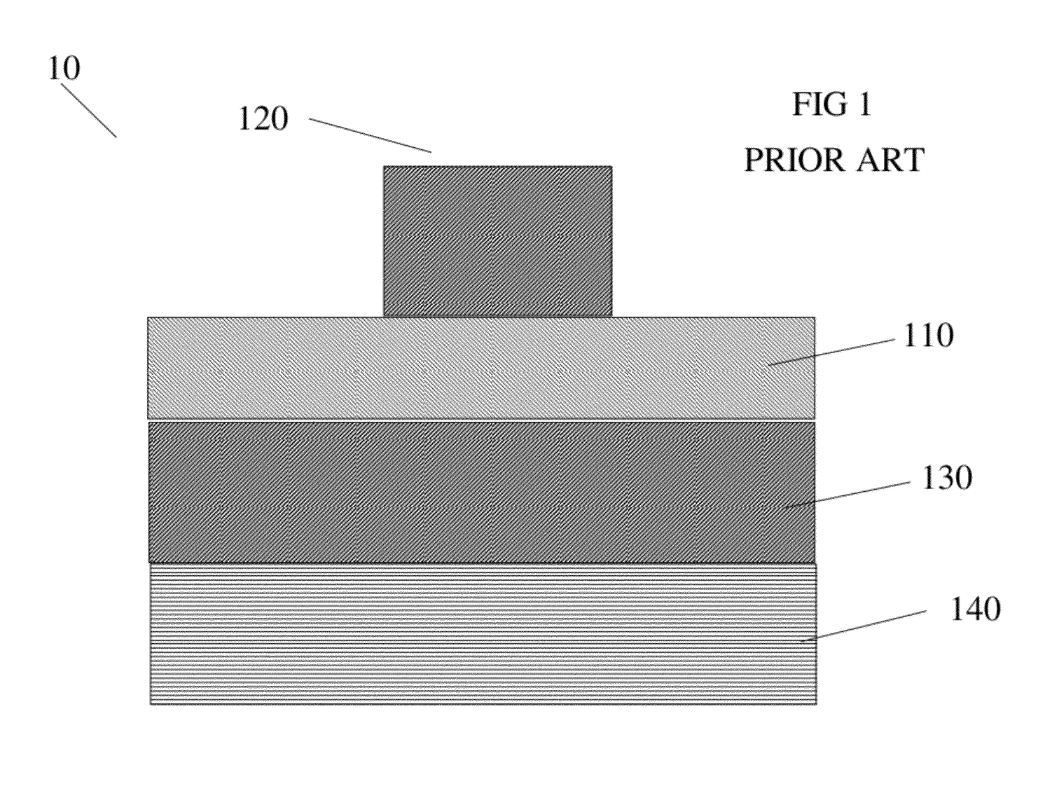

Consider the structure of this invention shown in FIG. 2. If each section of electroluminescent material between the electrodes 220 has a depth d and thickness t, the total volume of material in each trench is given by l×t×d where l is the length of the trench. If the distance or pitch between trenches is p, then the number of trenches in area A is given by w/p. The total volume of material associated with area A is then l×t×d×w/p or A×t×d/p. So the amount of material that is contained in the same area A when the luminescent material is disposed in trenches is enhanced by a factor d/p over the case where the active film is deposited in planar fashion as in FIG. 1. In typical state of the art technologies, trench depths of 10 microns and pitch of 0.2 microns are achievable. These dimensions show that fill factor enhancements of 50 or more are possible over those achieved with deposited planar films structure in prior art. By appropriately choosing the trench depth and electrode pitch, the solid state light emitting device of this invention can achieve luminosities per unit area which are increased an order of magnitude or more over that of the prior art.

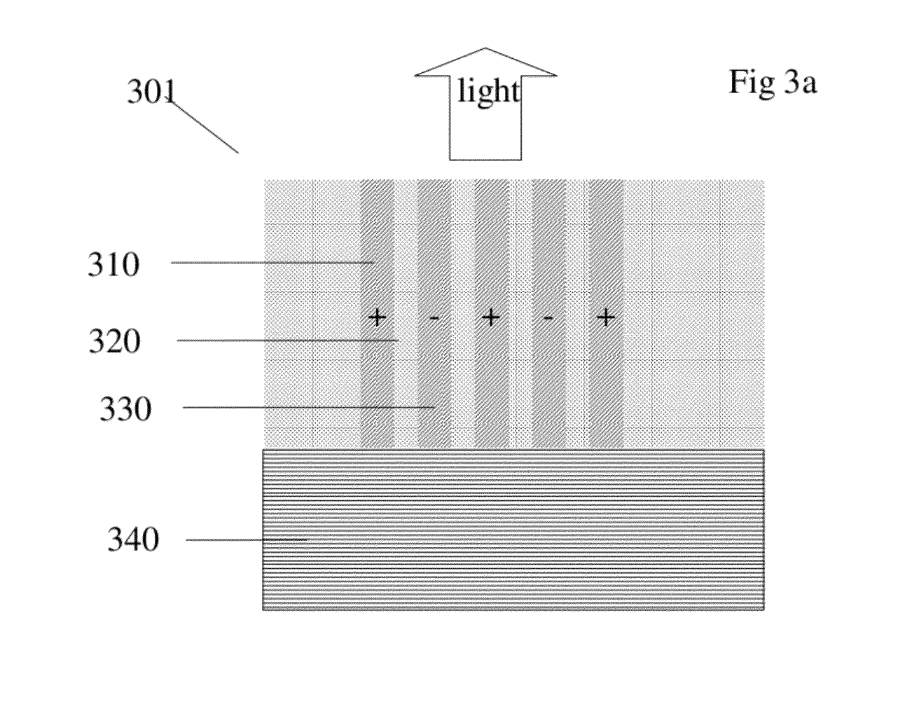

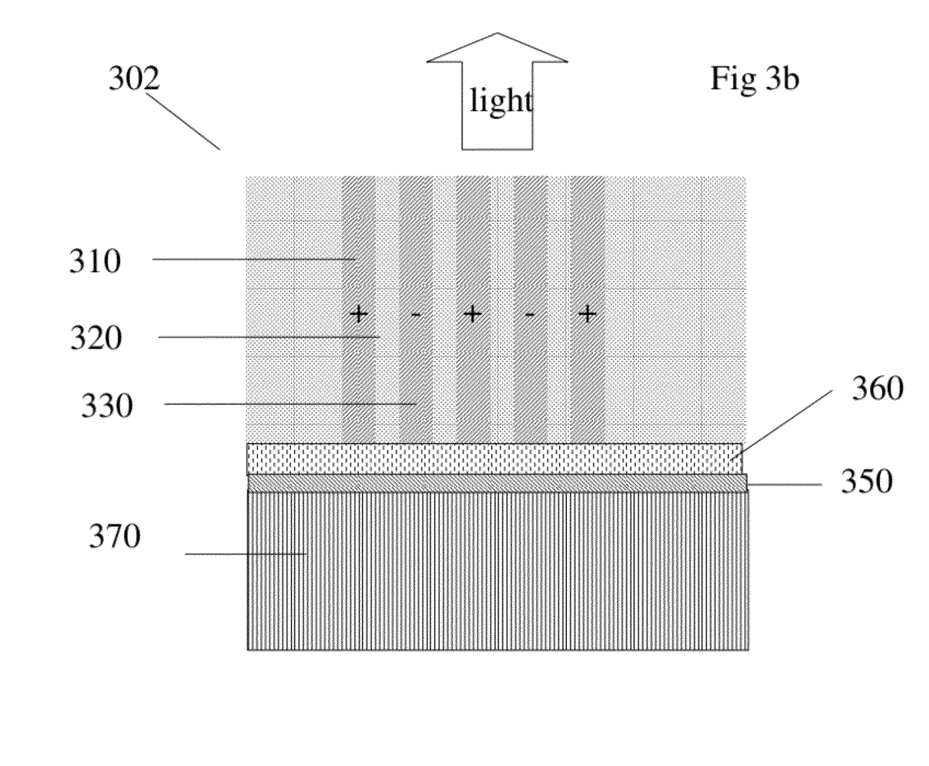

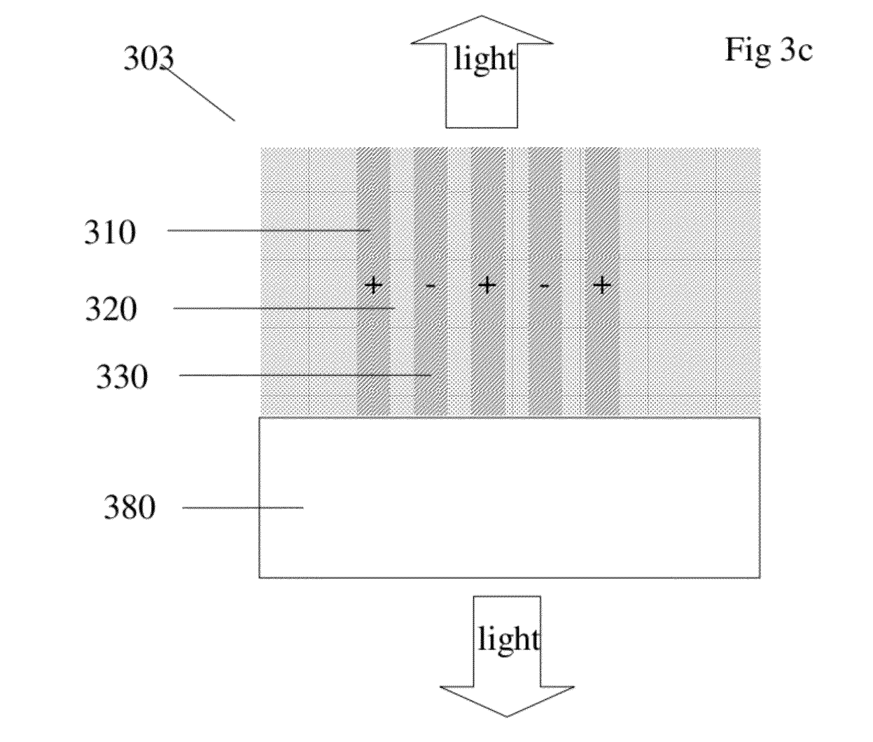

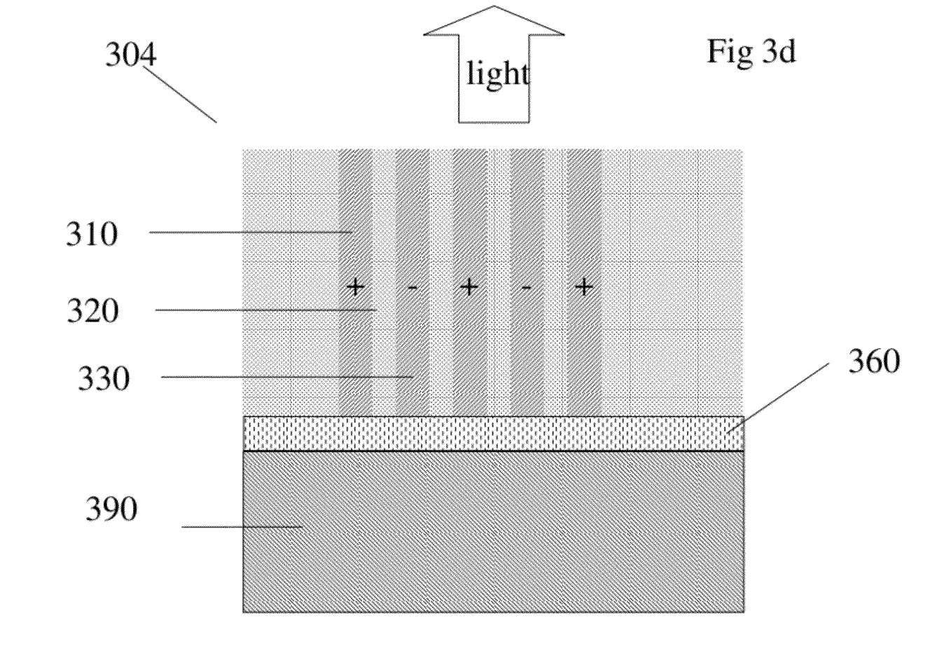

FIG. 3a is a cross-sectional view of a first embodiment of the present invention where the electroluminescent material 320 and the electrodes 310 and 330 are deposited on an opaque non-conducting substrate to form LED device 301. Possible light emitting materials include epitaxially deposited crystalline III-V compounds, doped II-VI compounds, doped or un-doped non-crystalline porous silicon, doped or un-doped non-crystalline silicon rich silicon oxide (SRSO), and doped or un-doped silicon rich nitride (SRSN), In this embodiment light is absorbed in the substrate and emitted from the top surface of the device.

FIG. 3b is a cross-sectional view of a second embodiment of the present invention where the electroluminescent material 320 and the electrodes 310 and 330 are deposited on an opaque or transparent conducting or non-conducting substrate to form LED device 302. A metallic reflective layer 350 is added to increase emission from the top surface and an insulating layer 360 is added to provide electrical isolation of the electrodes 310 and 330. The insulating layer enhances the desired optical emission from the top surface.

FIG. 3c is a cross-sectional view of a third embodiment of the present invention where the electroluminescent material 320 and the electrodes 310 and 330 are deposited on a transparent non-conducting substrate 380 such as glass or plastic to form LED device 303. In this embodiment light is emitted from both the top and bottom surfaces of the light emitting diode.

FIG. 3d is a cross-sectional view of a fourth embodiment of the present invention where the electroluminescent material 320 and the electrodes 310 and 330 are deposited on a reflective conducting substrate 390 such as metal to form LED device 304. An insulating film such as glass, silicon nitride or plastic 360 is present over the substrate to provide electrical isolation for the electrodes and may be chosen to enhance the desired optical emission from the top surface.

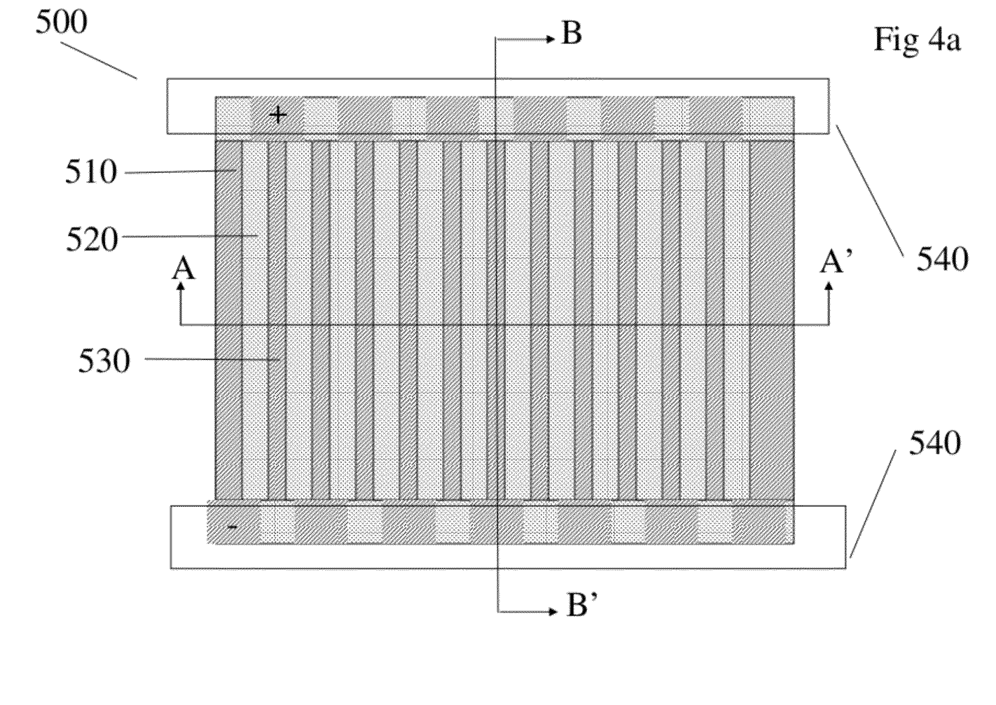

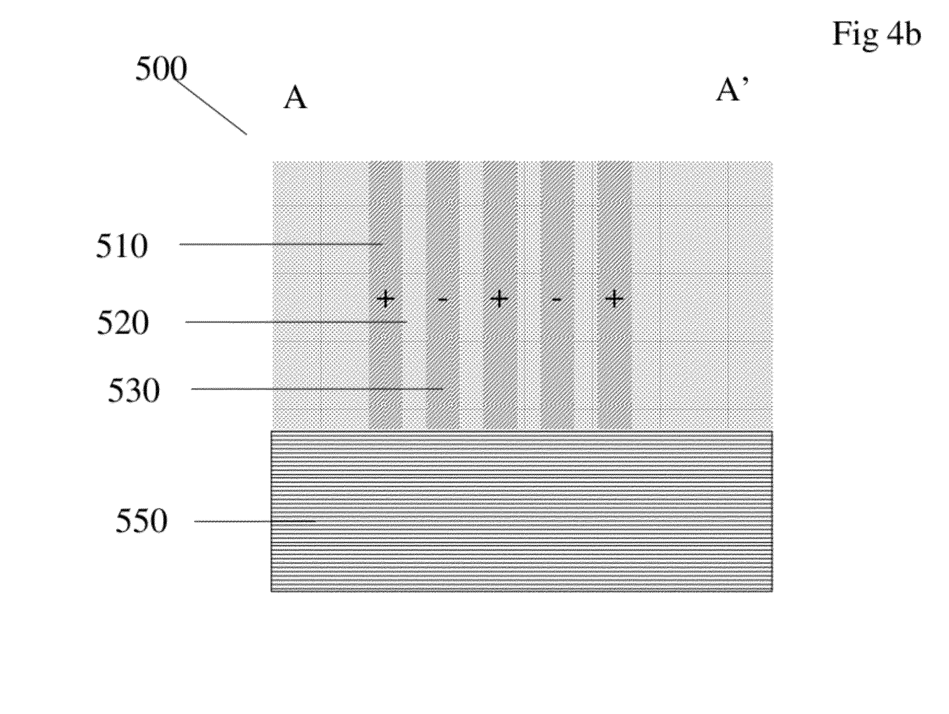

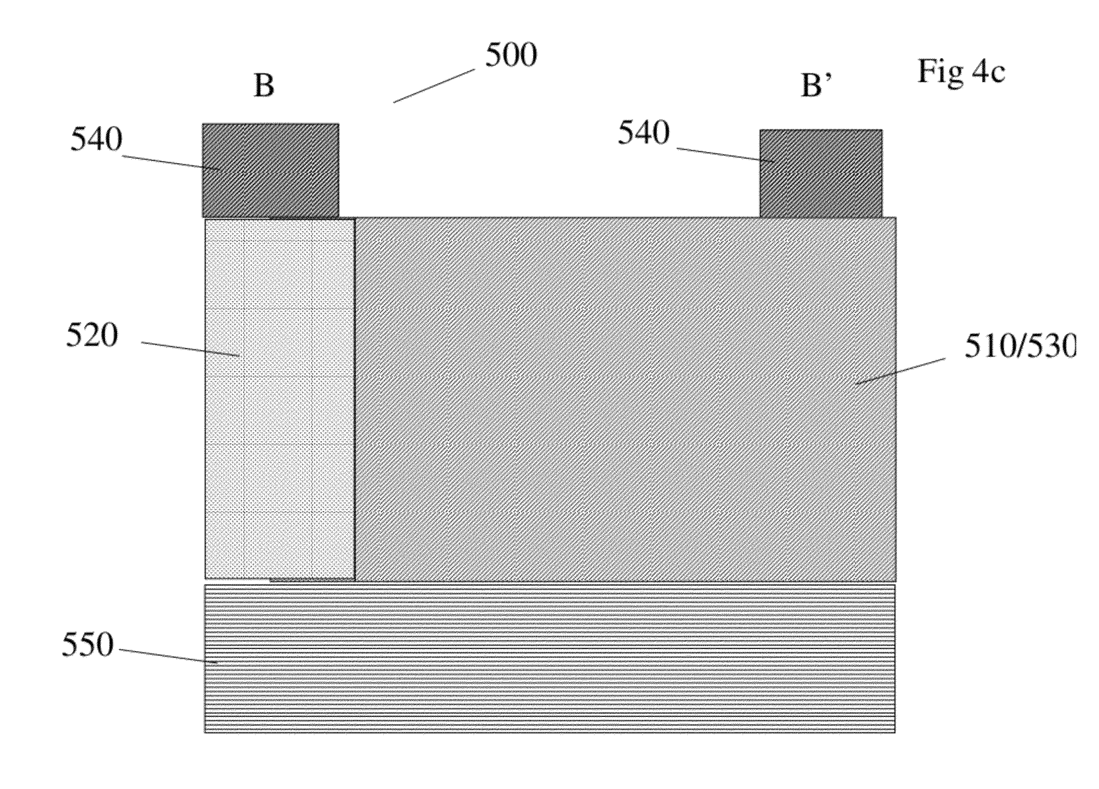

FIG. 4a is a plane view of the light emitting diode 500 with connections to positive and negative top surface power rails 540 connected to the trench electrodes 510 and 530 which apply an electric field across the electroluminescent material 520. This manner of connection to the power rails is only an example of a connection scheme and does not limit the use of other means.

FIG. 4b is a cross-sectional view through section A-A′ in FIG. 4a of light emitting diode 500. The electrodes 510 and 530 and the electroluminescent material 520 are shown deposited on the substrate 550 described in the first embodiment but it is understood that any of the described embodiments or variations thereof are also included.

FIG. 4c is a cross-sectional view through section B-B′ in FIG. 4a of the light emitting diode 500. The electrodes 510 or 530 and the electroluminescent material 520 are shown deposited on the substrate described in the first embodiment but it is understood to apply to that any of the described embodiments or variations thereof. Note that the electrode 510 extends from the top surface to the underlying substrate.

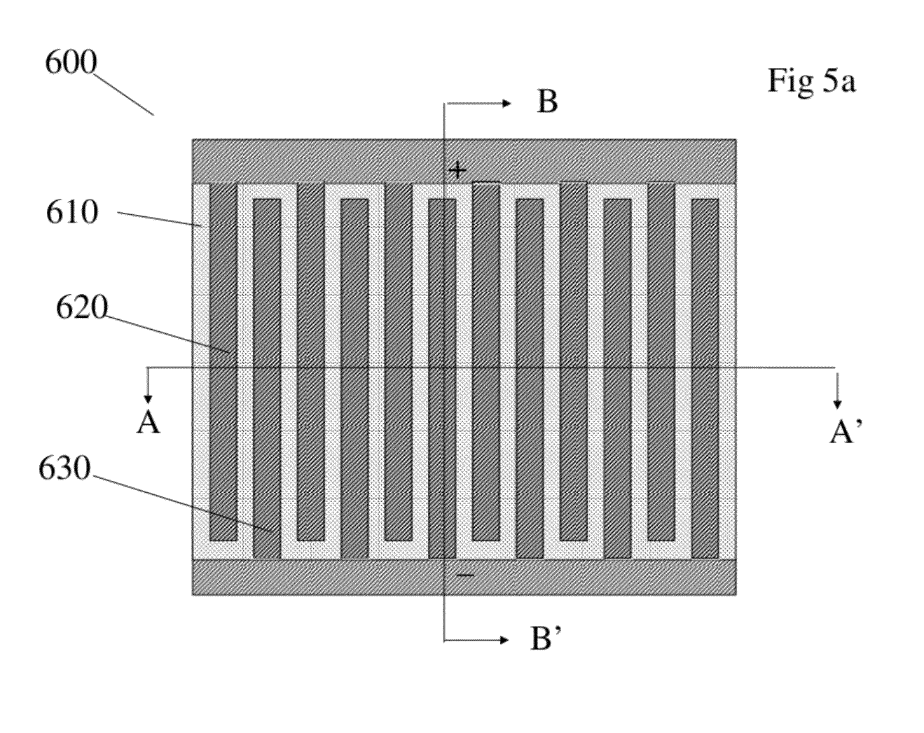

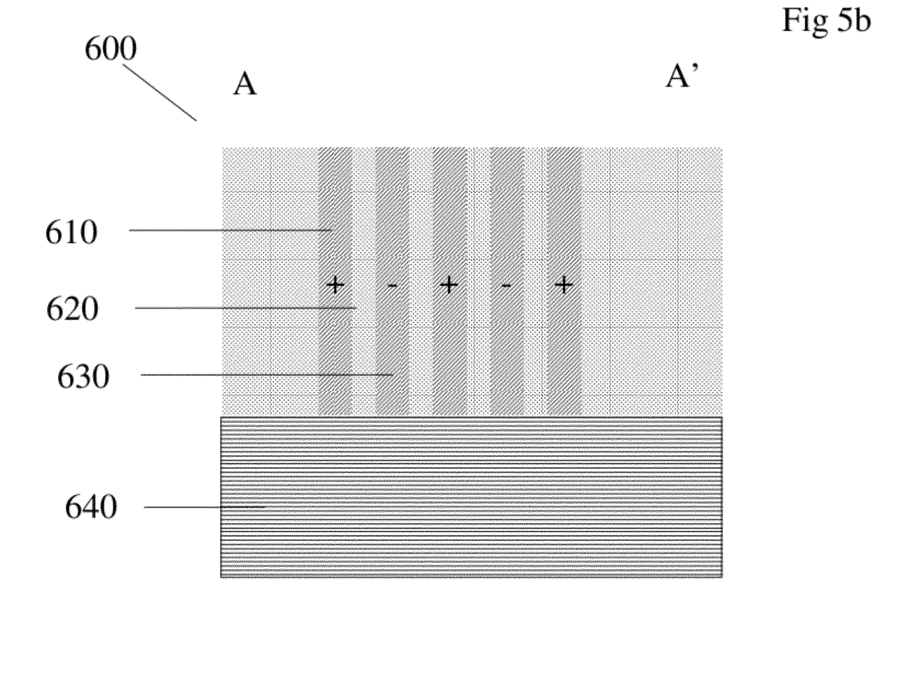

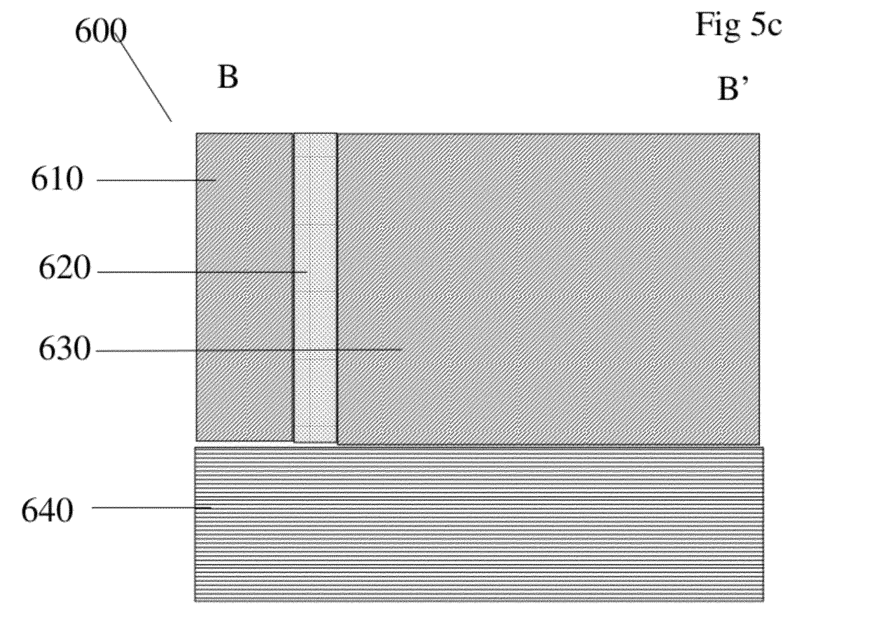

FIG. 5a is a plane view of the light emitting diode 600 where the positive and negative power rails 540 are integrated with the trench electrodes 610 and 630 which apply an electric field across the electroluminescent material 620. Low resisitivity metals such as but not limited to aluminum, copper, silver, gold can be used for this purpose. This manner of connection to the power rails is only an example of a connection scheme and does not limit the use of other means.

FIG. 5b is a cross-sectional view through section A-A′ in FIG. 5a of the light emitting diode 600. The electrodes 610 and 630 and the electroluminescent material 620 are shown deposited on the substrate described in the first embodiment but it is understood that any of the described embodiments or variations thereof are also included

FIG. 5c is a cross-sectional view through section B-B′ in FIG. 5a of the light emitting diode 600. The electrodes 610 and 630 and the electroluminescent material 620 are shown deposited on the substrate described in the first embodiment but it is understood to apply to any of the described embodiments or variations thereof. Note that the electrode 610 extends from the top surface to the underlying substrate and that the electroluminescent material 620 provides isolation between the positive and negative electrodes 610 and 630.

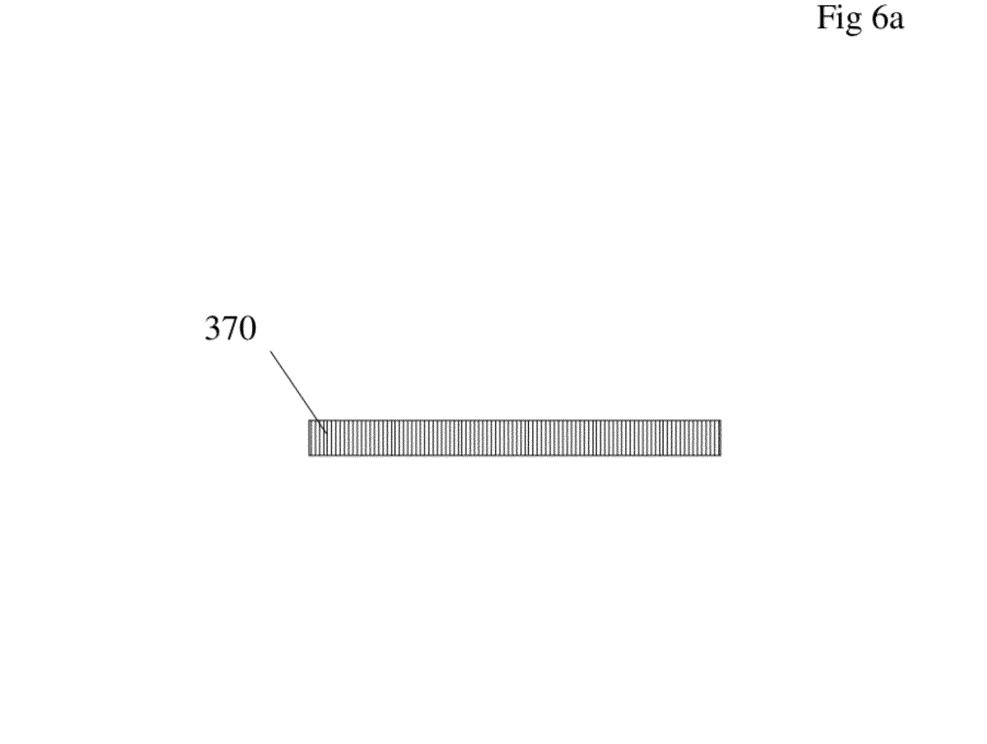

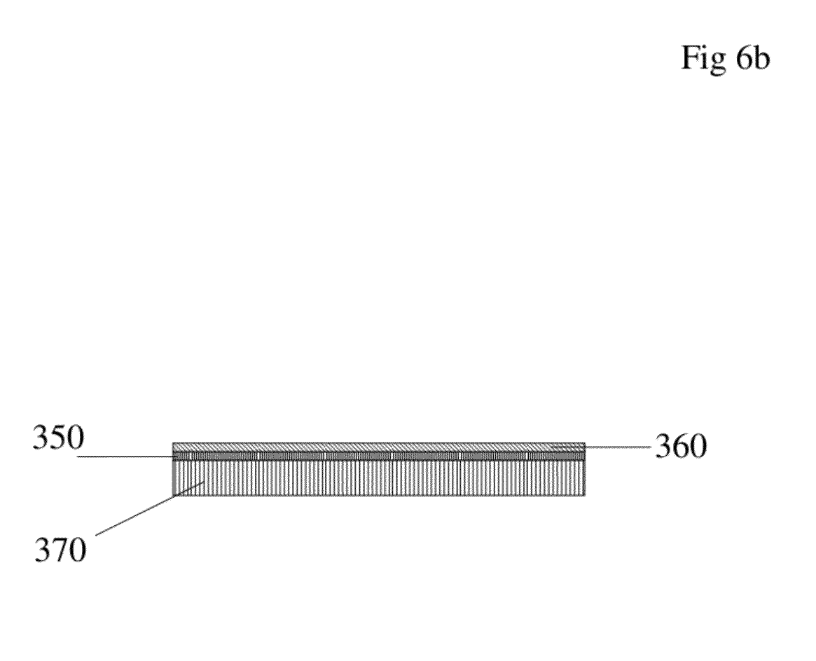

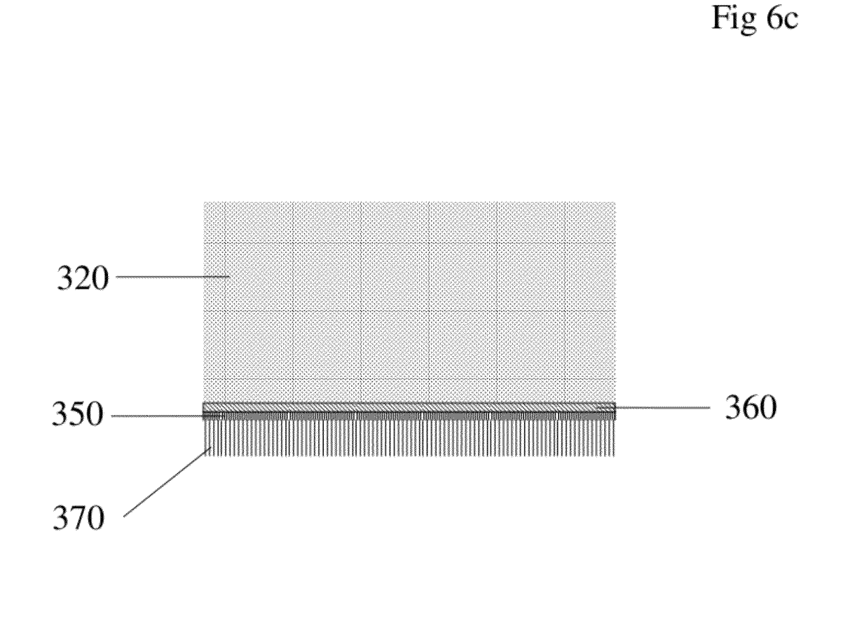

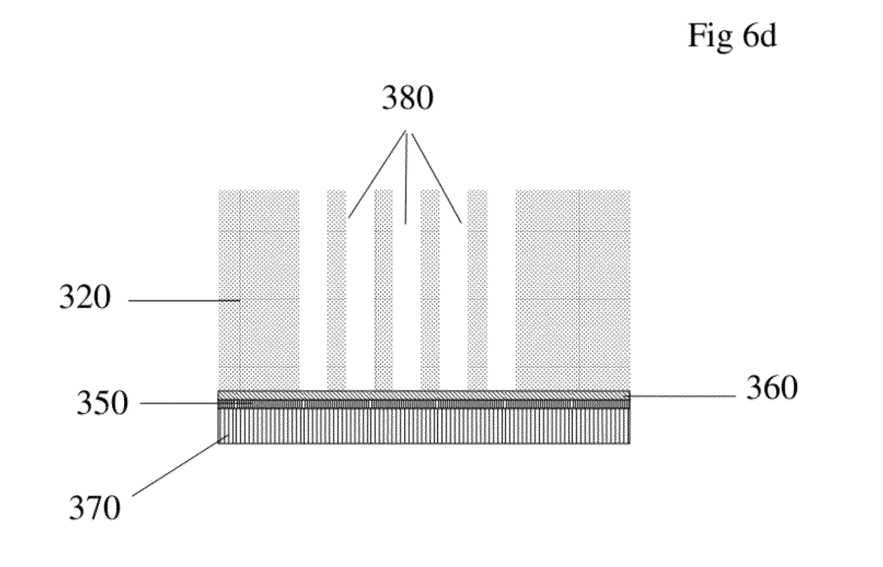

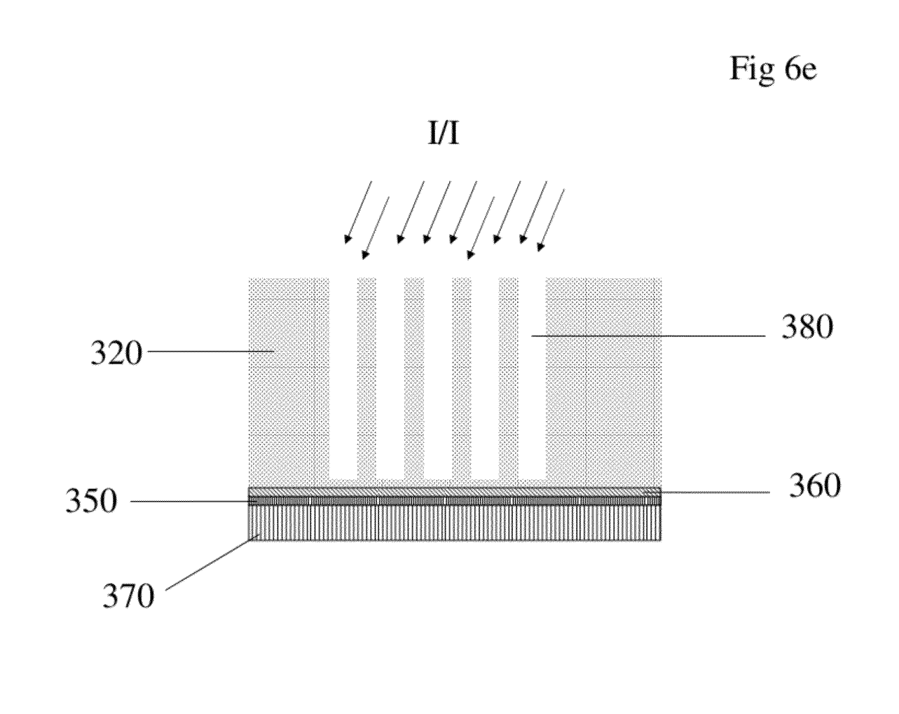

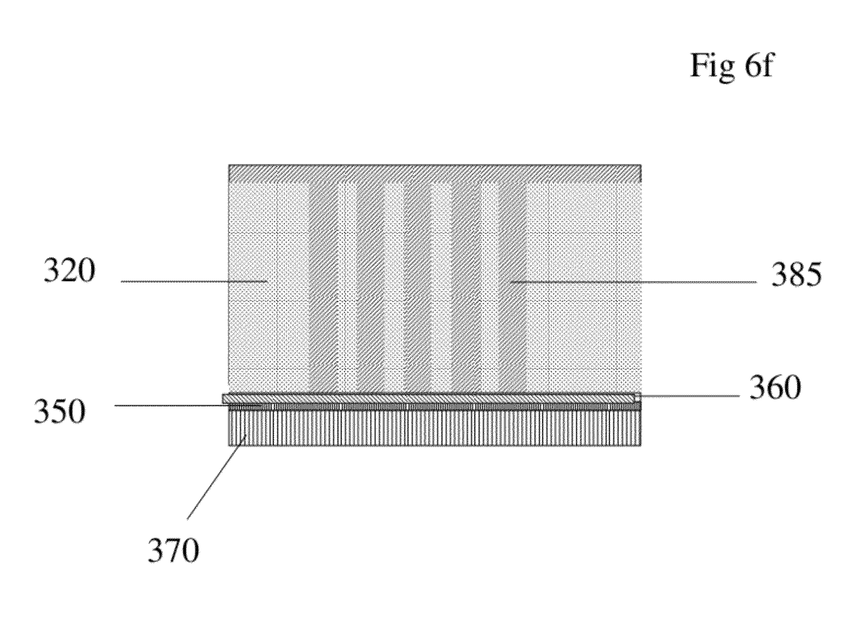

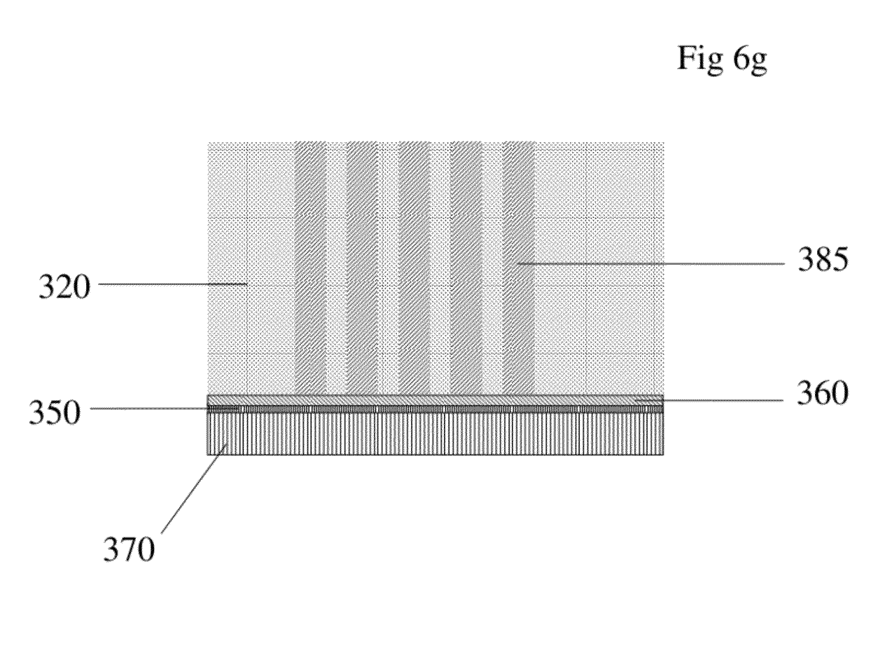

FIG. 6 a through g show a sequence of fabrication steps for the second embodiment of the present invention wherein a top surface emitting LED is fabricated. This embodiment was chosen as an example since it provides the most comprehensive sequence of steps. One of ordinary skill in the art could fabricate any of the other structures using the applicable fabrication steps described by this figure.

FIG. 6a shows the selection of a substrate 370 which may be either an insulator or a conductor and which may also be transparent or opaque to the light produced in the light emitting diode. This choice will dictate whether the LED will emit from the top surface only or from both the top and bottom surfaces consistent with the other embodiments described herein. As shown in FIG. 6 b a metallic reflective layer 350 is deposited onto the upper surface of the substrate to enhance the reflectivity of the light reaching that interface and direct it toward the upper surface of the light emitting diode. This film is optional in the case of a transparent substrate with emission from both the top and bottom surfaces. High reflectivity metallic films such as but not limited to aluminum titanium, tungsten, copper, silver or gold can be used. An insulating layer 360 is subsequently deposited on the metallic reflecting layer to isolate the electrodes, formed on this surface later in the process from each other. Films such as, but not limited to silicon dioxide, silicon nitride, polyimide or other insulators can be used in forming this layer. The electroluminescent material 320 is deposited on the insulating film as shown in FIG. 6c.

Electroluminescent materials such as gallium arsenide, gallium aluminum arsenide, III-V to II-VI direct band gap semiconductors, doped or un-doped silicon-rich oxide or silicon-rich nitride can be used as the luminescent material. The invention is not limited to a particular choice of luminescent material and any which can be grown or deposited in a planar fashion are useable. Trenches 380 are etched into the electroluminescent material 320 as illustrated in FIG. 6d. Typical etching processes such as reactive ion etching used in state of the art semiconductor fabrication processes or tailored to etch the luminescent material can be used. Any ion implantation step needed to tune or activate the emissions from the light emitting material are performed at this point as shown in FIG. 6e In the case of silicon-rich silicon dioxide or silicon-rich nitride, implantation of silicon to tailor the light emission would be done at this point. In the case of other electroluminescent materials other dopant ions would be chosen for ion implantation as appropriate. FIG. 6f illustrates the filling of the trenches 380 with a metallic conductor 385. The metal may be any of the low resistivity metals commonly used in state of the art semiconductor fabrication but not limited to them The excess metal is subsequently removed from the top surface of the structure by standard processing techniques such as chemical mechanical polishing or reactive ion etching resulting in the finished structure as shown in FIG. 6g. Variations on this sequence of steps and materials leading to other LED structures are not excluded by the above process

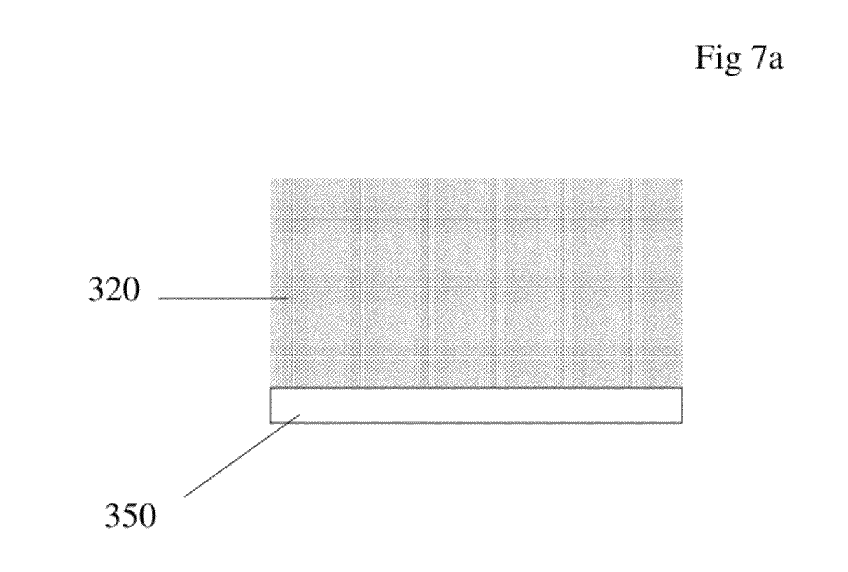

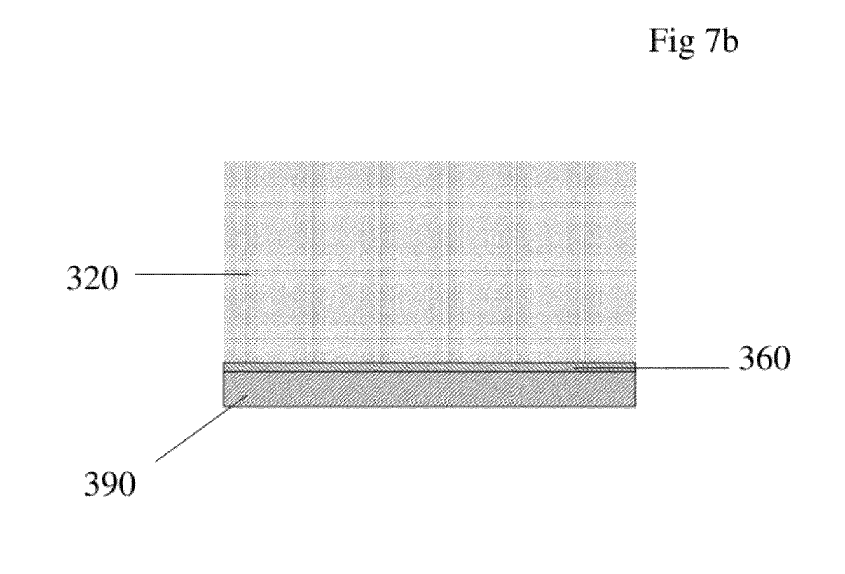

Other embodiments of this invention with different substrate types can be fabricated using the same processing steps described in FIG. 6a through FIG. 6g. As illustrated in FIG. 7a, given a transparent non-conducting substrate 350 upon which is deposited electroluminescent material, the sequence outlined above will lead to the third embodiment of the present invention shown in FIG. 3c. Similarly given a metallic substrate 390 with an insulating layer 360 deposited thereon as depicted in FIG. 7b, the same process sequence described above will lead to the fourth embodiment of the present invention shown in FIG. 3d.

Although the foregoing method of manufacture has been described in some detail for the purposes of clarity of understanding, it will be apparent that certain changes and modifications may be practiced within the scope of the appended claims. Accordingly the present embodiments are to be considered as illustrative not restrictive and the invention is not to be limited to the details given herein.

What is claimed is:

1. A light emitting diode with a top light emitting surface comprising a substrate with a top surface also comprising a light emitting material disposed on said top surface of said substrate and also comprising at least one metal electrode disposed inside a trench in said light emitting material, the depth of said trench extending substantially perpendicular to said top light emitting surface of said light emitting diode into said light emitting material.

2. A light emitting diode as in claim 1 wherein the substrate is an electrical conductor having a top and bottom surface also comprising a reflective metallic film having a top and bottom surface disposed on the top surface of said substrate and also comprising a thin insulating film disposed between the top surface of said reflective metallic film and the light emitting material.

3. A light emitting diode as in claim 2 where the electrically conducting substrate is silicon.

4. A light emitting diode as in claim 2 where the electrically conducting substrate is metal

5. A light emitting diode as in claim 1 wherein the substrate is an optically transparent material.

6. A light emitting diode wherein the substrate is an optically transparent material having a top and a bottom surface also comprising a reflective metallic film having a top and bottom surface disposed on the top surface of said silicon substrate.

7. A light emitting diode wherein the substrate is an optically transparent material having a top and a bottom surface also comprising a reflective metallic film having a top and bottom surface disposed on the top surface of said silicon substrate and also comprising a thin insulating film disposed between the top surface of said reflective metallic film and the light emitting material.

8. A light emitting diode as in claim 6 where the transparent material is glass.

9. A light emitting diode as in claim 6 where the transparent material is a plastic.

10. A light emitting diode as in claim 1 where the light emitting material is any one of the group of light emitting materials consisting of silicon-rich oxide, silicon-rich oxide doped with rare earth elements, silicon-rich nitride, silicon-rich nitride doped with rare earth metals, II-VI semiconductors doped with light emitting elements or III-V semiconductors.

11. A method for fabricating a light emitting diode comprising supplying a silicon substrate, growing or depositing a thin reflective metal film, depositing an electrically insulating thin film such as silicon nitride, depositing a light emitting material, patterning said light emitting material to form at least one trench in the material, implanting appropriate ions into said light emitting film as needed, annealing or oxidizing said light emitting material film to optimize its optical emission efficiency, depositing electrically conducting metal in the opening formed by patterning and etching the at least one trench, removing the excess metal, depositing and patterning metal to form contacts to the sidewall electrodes.

12. A method for fabricating a light emitting diode comprising supplying a metal substrate, growing or depositing a thin reflective metal film, depositing an electrically insulating thin film such as silicon nitride, depositing a light emitting material, patterning said light emitting material to form at least one trench in the material, implanting appropriate ions into said light emitting film as needed, annealing or oxidizing said light emitting material film to optimize its optical emission efficiency, depositing electrically conducting metal in the opening formed by patterning and etching the at least one trench, removing the excess metal, depositing and patterning metal to form contacts to the sidewall electrodes

13. A method for fabricating a light emitting diode comprising supplying a transparent, insulating substrate, growing or depositing a thin reflective metal film, depositing an electrically insulating thin film such as silicon nitride, depositing a light emitting material, patterning said light emitting material to form at least one trench in the material, implanting appropriate ions into said light emitting film as needed, annealing or oxidizing said light emitting film to optimize its optical emission efficiency, depositing electrically conducting metal in the opening formed by patterning and etching the at least one trench, removing any excess metal, depositing and patterning metal to form contacts to the sidewall electrodes.

14. A method for fabricating a light emitting diode comprising supplying a transparent insulating substrate, depositing a light emitting material, patterning and etching the light emitting material to form at least one trench in the material, implanting the appropriate ions into the material, annealing or oxidizing said light emitting film to optimize its optical emission efficiency, depositing electrically conducting metal in the openings formed by patterning and etching the at least one trench, removing the excess metal, depositing and patterning the metal to form contacts to the sidewall electrodes.

15. A method for fabricating the light emitting diode as in claim 11, where the light emitting material is any one of the light emitting materials contained in the group of light emitting materials consisting of silicon-rich oxide, silicon-rich oxide doped with rare earth elements, silicon-rich nitride, silicon-rich nitride doped with rare earth metals, II-VI semiconductors doped with light emitting elements or III-V semiconductors.

16. A method for fabricating the light emitting diode as in claim 12, where the light emitting material is any one of the light emitting materials contained in the group of light emitting materials consisting of silicon-rich oxide, silicon-rich oxide doped with rare earth elements, silicon-rich nitride, silicon-rich nitride doped with rare earth metals, II-VI semiconductors doped with light emitting elements or III-V semiconductors.

17. A method for fabricating the light emitting diode as in claim, 13 where the light emitting material is any one of the light emitting materials contained in the group of light emitting materials consisting of silicon-rich oxide, silicon-rich oxide doped with rare earth elements, silicon-rich nitride, silicon-rich nitride doped with rare earth metals, II-VI semiconductors doped with light emitting elements or III-V semiconductors.

18. A method for fabricating the light emitting diode as in claim, 14 where the light emitting material is any one of the light emitting materials contained in the group of light emitting materials consisting of silicon-rich oxide, silicon-rich oxide doped with rare earth elements, silicon-rich nitride, silicon-rich nitride doped with rare earth metals, II-VI semiconductors doped with light emitting elements or III-V semiconductors.
